(19) United States
(12) Patent Application Publication
(10) Pub. No.: US 2023/0268885 A1
(43) Pub. Date: Aug. 24, 2023

(54) Oscillator

(71) Applicant: SEIKO EPSON CORPORATION, Tokyo (JP)

(72) Inventors: Norihito MATSUKAWA, Shimosuwa (JP); Manabu KONDO, Matsumoto (JP)

(21) Appl. No.: 18/171,738

(22) Filed: Feb. 21, 2023

(30) Foreign Application Priority Data
Feb. 22, 2022 (JP) 2022-025381

(51) Int. Cl. H03B 5/04; H03B 5/32; H10N 30/88; H10N 30/87

(52) U.S. Cl. CPC H03B 5/04; H03B 5/32; H10N 30/88; H10N 30/87

(57) ABSTRACT

An oscillator includes: a first resonator element, a first package that accommodates the first resonator element and includes a base and a lid, a heater element that is attached to the first package, a second package that accommodates the first package, a control circuit element that is bonded to a surface of the base of the first package on a side opposite to the lid and is configured to control the heater element, and a first heat insulating member that is provided between the lid of the first package and the second package.

The present application is based on, and claims priority from JP Application Serial Number 2022-025381, filed Feb. 22, 2022, the disclosure of which is hereby incorporated by reference herein in its entirety.

### BACKGROUND

### 1. Technical Field

The present disclosure relates to an oscillator.

### 2. Related Art

JP-A-2017-130861 discloses a quartz crystal oscillator in which a package body in which a heater unit and a quartz crystal resonator are accommodated is stored in a container formed by a base substrate and a cover case. In this quartz crystal oscillator, the package body is supported by a plurality of spacers disposed on the base substrate.

However, in the quartz crystal oscillator of JP-A-2017-130861, in order to electrically couple the package body and the base substrate, a conductive path formed by metal plating is formed in the spacer. Therefore, heat is easily transferred between the base substrate and the package body via the conductive path that is formed by metal plating and formed in the spacer. Therefore, there is a problem that heat from the outside of the quartz crystal oscillator is easily transmitted to the quartz crystal resonator accommodated in the package body via the spacer, and oscillation characteristics of the quartz crystal oscillator are easily affected by an ambient temperature.

### SUMMARY

An oscillator includes: a first resonator element; a first package that accommodates the first resonator element and includes a base and a lid; a heater element that is attached to the first package; a second package that accommodates the first package; a control circuit element that is bonded to a surface of the base of the first package on a side opposite to the lid and is configured to control the heater element; and a first heat insulating member that is provided between the lid of the first package and the second package.

### BRIEF DESCRIPTION OF THE DRAWINGS

FIG. 1 is a cross-sectional view of an oscillator according to a first embodiment.

FIG. 2 is a cross-sectional view of a first resonator in FIG. 1.

FIG. 3 is a cross-sectional view of a second resonator in FIG. 1.

FIG. 4 is a cross-sectional view of an oscillator according to a second embodiment.

FIG. 5 is a cross-sectional view of an oscillator according to a third embodiment.

FIG. 6 is a cross-sectional view of a first resonator in FIG. 5.

FIG. 7 is a cross-sectional view of an oscillator according to a fourth embodiment.

### DESCRIPTION OF EXEMPLARY EMBODIMENTS

Next, embodiments of the present disclosure will be described with reference to the drawings.

For convenience of description, an X axis, a Y axis, and a Z axis are shown in each figure as three axes orthogonal to one another. A direction along the X axis is referred to as an “X direction”, a direction along the Y axis is referred to as a “Y direction”, and a direction along the Z axis is referred to as a “Z direction”. An arrow tip side in each axial direction is also referred to as a “plus side”, and an arrow proximal end side is also referred to as a “minus side”. For example, the Y direction refers to both a plus side in the Y direction and a minus side in the Y direction. A plus side in the Z direction is also referred to as “upper”, and a minus side in the Z direction is also referred to as “lower”. A plan view seen from the Z direction is also simply referred to as a “plan view”.

### 1. First Embodiment

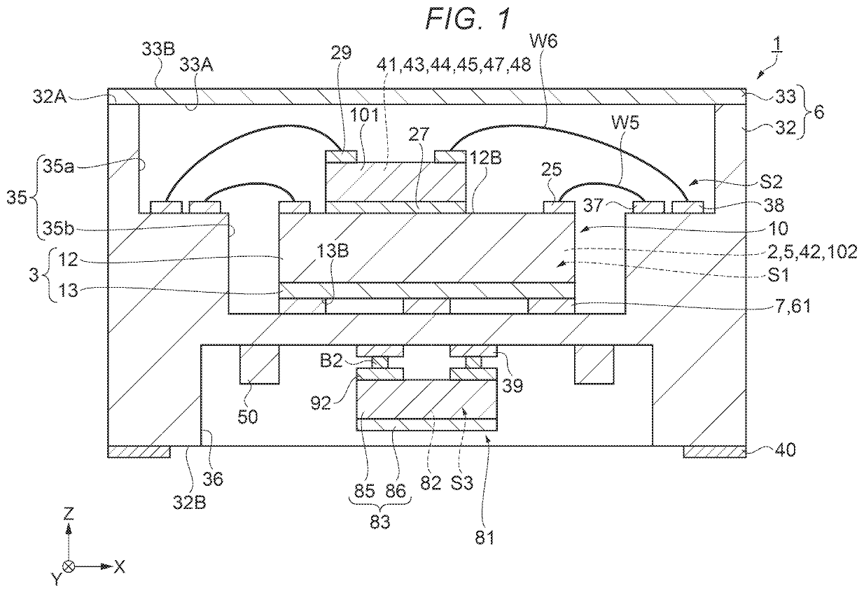

An oscillator 1 according to a first embodiment will be described with reference to FIGS. 1, 2, and 3.

The oscillator 1 shown in FIG. 1 is an oven controlled crystal oscillator (OCXO).

As shown in FIG. 1, the oscillator 1 includes a first resonator element 2, a first package 3 that accommodates the first resonator element 2, a heater element 5 that is attached to the first package 3 and that heats the first resonator element 2, a second package 6 that accommodates the first package 3, a first circuit element 101 as a control circuit element that includes a heater control circuit 41 controlling the heater element 5, and a first heat insulating member 7 that is provided between the first package 3 and the second package 6. Specifically, the first package 3 includes a first base substrate 12 as a base of the first package 3 and a first lid 13 as a lid of the first package 3. The first heat insulating member 7 is provided between the first lid 13 of the first package 3 and the second package 6. The first lid 13 of the first package 3 is fixed to the second package 6 via the first heat insulating member 7. In the embodiment, the first resonator element 2 and the first package 3 are also collectively referred to as a first resonator 10.

The oscillator 1 further includes a second circuit element 102 including an oscillation circuit 42 that causes the first resonator element 2 to oscillate so as to generate an oscillation signal, and a second resonator 81. The second resonator 81 constitutes a part of a phase locked loop (PLL) circuit 43 to be described later.

In such an oscillator 1, the first resonator element 2 is heated by heat of the heater element 5, and the first resonator element 2 is maintained at a desired temperature, so that frequency variation of an oscillation signal output from the oscillator 1 is prevented, and excellent oscillation characteristics are implemented.

First, the first resonator 10 will be described.

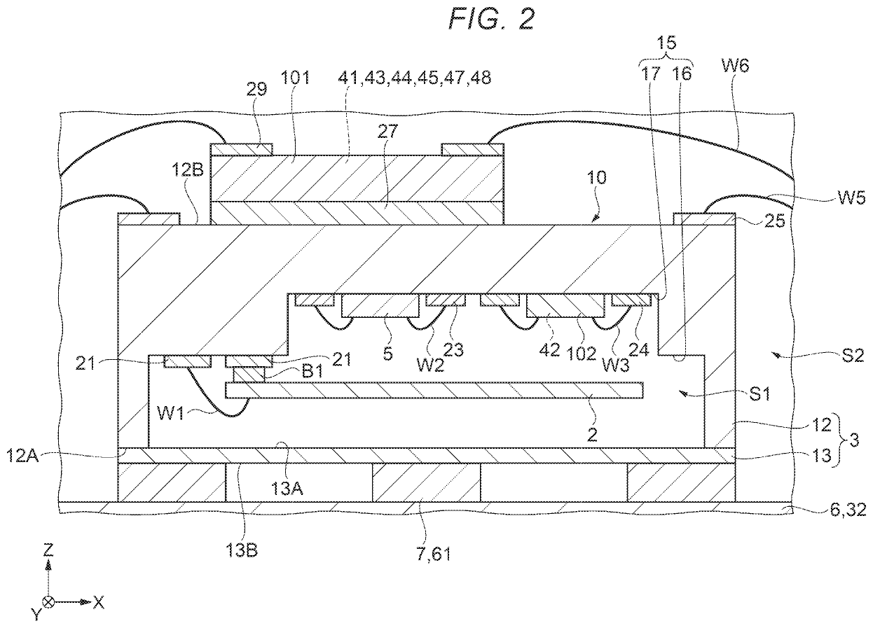

As shown in FIG. 2, the first resonator 10 includes the first resonator element 2 and the first package 3.

The first resonator element 2 is formed of a quartz crystal substrate having a flat plate shape. In the embodiment, the first resonator element 2 is formed of an SC cut quartz crystal substrate. Excitation electrodes (not shown) are provided on an upper surface and a lower surface of the first resonator element 2.

However, the configuration of the first resonator element 2 is not particularly limited. The first resonator element 2 may be formed of, for example, an AT cut quartz crystal substrate or a BT cut quartz crystal substrate other than the SC cut quartz crystal substrate. The first resonator element 2 may be, for example, a resonator element in which a plurality of resonating arms perform flexural resonation in an in-plane direction, or a resonator element in which a plurality of resonating arms perform the flexural resonation in an out-of-plane direction. Further, the first resonator element 2 may be, for example, a resonator element in which a piezoelectric body other than a quartz crystal is used. Further, the first resonator element 2 may be, for example, a surface acoustic wave (SAW) resonator, or a micro electro mechanical systems (MEMS) resonator in which a piezoelectric element is disposed on a semiconductor substrate made of silicon or the like.

The first package 3 includes the first base substrate 12 and the first lid 13.

The first base substrate 12 has a box shape in which a concave portion 15 is formed. The concave portion 15 has a shape that opens in a lower surface 12A, and is recessed toward an upper surface 12B.

The first lid 13 has a flat plate shape. The first lid 13 has an upper surface 13A which is a surface facing the first base substrate 12, and a lower surface 13B.

The lower surface 12A of the first base substrate 12 and the upper surface 13A of the first lid 13 are bonded to each other via a sealing member (not shown) so as to close an opening of the concave portion 15. As a result, the concave portion 15 is hermetically sealed, and a first accommodation space S1 is formed in the first package 3. Then, the first resonator element 2 is accommodated in the first accommodation space S1.

By bonding the lower surface 12A of the first base substrate 12 and the upper surface 13A of the first lid 13, a surface of the first base substrate 12 on a side opposite to the first lid 13 becomes the upper surface 12B of the first base substrate 12. In addition, the upper surface 12B of the first base substrate 12 becomes an upper surface of the first package 3, and the lower surface 13B of the first lid 13 becomes a lower surface of the first package 3.

In the embodiment, the first base substrate 12 is made of a ceramic material such as alumina or titania. The first lid 13 is made of a metal material such as Kovar. However, the constituent materials of the first base substrate 12 and the first lid 13 are not particularly limited.

The first accommodation space S1 is airtight and is in a reduced pressure state, preferably in a state close to vacuum. That is, the inside of the first package 3 is depressurized. As a result, a viscosity resistance of the first accommodation space S1 is reduced, and resonation characteristics of the first resonator element 2 are improved. An atmosphere of the first accommodation space S1 is not particularly limited.

The concave portion 15 includes a plurality of concave portions. In the embodiment, the concave portion 15 includes a concave portion 16 that opens in the lower surface 12A of the first base substrate 12, and a concave portion 17 that opens in a bottom surface of the concave portion 16 and has an opening smaller than that of the concave portion 16. However, the configuration of the concave portion 15 is not particularly limited.

A plurality of internal terminals 21 are disposed on the bottom surface of the concave portion 16. The plurality of internal terminals 21 are electrically coupled to the first resonator element 2 via conductive bonding members B1 and conductive bonding wires W1. Specifically, the internal terminal 21 is electrically coupled to the excitation electrodes (not shown) provided on the upper surface and the lower surface of the first resonator element 2 via the bonding members B1 and the bonding wires W1. A method for supporting the first resonator element 2 is not limited to a one-point support by the bonding member B1, and may be, for example, a two-point support by two bonding members.

The bonding member B1 is a metal bump formed of gold, copper, or the like. The bonding wire W1 is a metal wire formed of gold, copper, or the like.

One end portion of the first resonator element 2 is fixed to the bottom surface of the concave portion 16 via the bonding member B1.

A plurality of internal terminals 23 and 24, the heater element 5, and the second circuit element 102 are disposed on a bottom surface of the concave portion 17.

The heater element 5 includes a heating circuit (not shown). The heating circuit functions as a heat generating portion that heats the first resonator element 2.

The heater element 5 is bonded to the bottom surface of the concave portion 17 by a bonding member (not shown). That is, in the embodiment, the heater element 5 is attached to the first package 3, and specifically, the heater element 5 is accommodated in the first package 3.

Although the heater element 5 is accommodated in the first package 3 in the embodiment, the heater element 5 may not be accommodated in the first package 3. For example, the heater element 5 may be attached to an outer peripheral surface of the first package 3.

However, since the heater element 5 is accommodated in the first package 3, the heat of the heater element 5 can be efficiently transferred to the first resonator element 2. Therefore, the heater element 5 can be efficiently driven, and the temperature of the first resonator element 2 can be easily maintained at a desired temperature. Accordingly, it is preferable that the heater element 5 is accommodated in the first package 3.

The plurality of internal terminals 23 are electrically coupled to the heater element 5 via conductive bonding wires W2.

The bonding wire W2 is a metal wire formed of gold, copper, or the like. A method for coupling the internal terminal 23 and the heater element 5 is not limited to the wire bonding using a metal wire, and may be flip chip bonding using, for example, a bump member.

The second circuit element 102 includes the oscillation circuit 42 that causes the first resonator element 2 to oscillate so as to generate an oscillation signal, and a temperature sensor (not shown).

The second circuit element 102 is an integrated circuit (IC) chip.

The oscillation circuit 42 is a circuit for generating the oscillation signal by outputting an excitation signal for exciting the first resonator element 2 and causing the first resonator element 2 to oscillate.

The second circuit element 102 is bonded to the bottom surface of the concave portion 17 by a bonding member (not shown). That is, in the embodiment, the second circuit element 102 is attached to the first package 3, and specifically, the second circuit element 102 is accommodated in the first package 3.

The plurality of internal terminals 24 are electrically coupled to the second circuit element 102 via the conductive bonding wires W3. The internal terminals 24 are electrically coupled to the internal terminals 21 via an internal wiring (not shown) formed in the first base substrate 12.

The bonding wire W3 is a metal wire formed of gold, copper, or the like. A method for coupling the internal terminal 24 and the second circuit element 102 is not limited to the wire bonding using a metal wire, and may be the flip chip bonding using, for example, a bump member.

By accommodating the second circuit element 102 including the oscillation circuit 42 in the first package 3, a length of a wiring that electrically couples the oscillation circuit 42 and the first resonator element 2 can be made shorter. Therefore, noise is less likely to be mixed from the wiring, and an oscillation signal with high accuracy can be generated. In FIG. 2, the heater element 5 is disposed at a position closer to the first resonator element 2 than the second circuit element 102, but the second circuit element 102 may be disposed at a position closer to the first resonator element 2 than the heater element 5.

A plurality of external terminals 25 are disposed on the upper surface 12B of the first base substrate 12.

The external terminals 25 are electrically coupled to the internal terminals 21, 23, and 24 via an internal wiring (not shown) formed in the first base substrate 12.

As shown in FIGS. 1 and 2, the first circuit element 101 is disposed on the upper surface 12B of the first base substrate 12.

The first circuit element 101 is an IC chip.

The first circuit element 101 includes the heater control circuit 41 that controls operations of the heater element 5, a part of the PLL circuit 43 to be described later, and a temperature sensor (not shown). Specifically, the first circuit element 101 includes an oscillation circuit 44, a phase comparator 45, a loop filter 47, and a dividing circuit 48 as a part of the PLL circuit 43.

The temperature sensor included in each of the first circuit element 101 and the second circuit element 102 functions as a temperature detection unit that detects an ambient temperature, in particular, a temperature of the first resonator element 2.

The heater control circuit 41 is a circuit for controlling an amount of current flowing through the heating circuit (not shown) included in the second heater element 5 based on an output signal of the temperature sensor included in the second circuit element 102 to maintain the first resonator element 2 at a constant temperature. For example, when a current temperature determined based on the output signal of the temperature sensor is lower than a set reference temperature, the heater control circuit 41 performs control such that a desired current flows through the heating circuit, and when the current temperature is higher than the reference temperature, the heater control circuit 41 performs control such that the current does not flow through the heating circuit.

In addition to the heater control circuit 41 and the PLL circuit 43, the first circuit element 101 may include the temperature compensation circuit that corrects the resonation characteristics of the first resonator element 2 according to a temperature change, the electrostatic protection circuit, and the like.

A bonding member 27 is provided between a lower surface of the first circuit element 101 and the upper surface 12B of the first base substrate 12. The first circuit element 101 is bonded to the upper surface 12B of the first base substrate 12 by the bonding member 27. That is, the first circuit element 101 and the first package 3 are bonded by the bonding member 27.

In the present embodiment, the bonding member 27 is a conductive adhesive. In general, in a conductive adhesive, a material having a high thermal conductivity such as silver, nickel, or graphite is added as a conductive filler to a resin material such as an epoxy resin or a silicone resin. Therefore, the conductive adhesive has a relatively high thermal conductivity.

By using the conductive adhesive having a relatively high thermal conductivity as the bonding member 27, heat is easily transferred between the first package 3 that accommodates the first resonator element 2 and the first circuit element 101 including the temperature sensor, and the temperature of the first resonator element 2 can be easily detected by the temperature sensor included in the first circuit element 101. Therefore, frequency-temperature characteristics of the first resonator element 2 can be corrected with high accuracy.

In addition, by using the conductive adhesive having a relatively high thermal conductivity as the bonding member 27, heat generated by operating the first circuit element 101 can be efficiently transferred to the first package 3 via the bonding member 27. Since the heat of the first circuit element 101 can be efficiently transferred to the first resonator element 2, the temperature of the first resonator element 2 can be easily maintained at the desired temperature together with the heater element 5.

The bonding member 27 may not be the conductive adhesive. For example, the bonding member 27 may be an insulating adhesive having a thermal conductivity in which an insulating filler having a high thermal conductivity such as aluminum nitride or aluminum oxide is added to a resin material.

A plurality of coupling terminals 29 are disposed on an upper surface of the first circuit element 101. The coupling terminals 29 are electrically coupled to the heater control circuit 41 included in the first circuit element 101 and the PLL circuit 43 via an internal wiring (not shown) in the first circuit element 101.

Next, the second package 6 that accommodates the first package 3 will be described.

As shown in FIG. 1, the second package 6 includes a second base substrate 32 and a second lid 33.

The second base substrate 32 has a box shape. The second base substrate 32 includes a concave portion 35 and a concave portion 36. The concave portion 35 has a shape that opens in an upper surface 32A of the second base substrate 32, and is recessed from the upper surface 32A toward a lower surface 32B. The concave portion 36 has a shape that opens in the lower surface 32B that is in a front-back relationship with the upper surface 32A, and is recessed from the lower surface 32B toward the upper surface 32A. Therefore, the second base substrate 32 has a substantially H shape in a longitudinal sectional view.

The concave portion 35 includes a plurality of concave portions. In the embodiment, the concave portion 35 includes a concave portion 35a that opens in the upper surface 32A of the second base substrate 32, and a concave portion 35b that opens in a bottom surface of the concave portion 35a and has the opening smaller than that of the concave portion 35a. However, the configuration of the concave portion 35 is not particularly limited.

A plurality of internal terminals 37 and 38 are disposed on the bottom surface of the concave portion 35a. The plurality of internal terminals 37 are electrically coupled to the first package 3. The plurality of internal terminals 38 are electrically coupled to the first circuit element 101.

The first package 3 is disposed on a bottom surface of the concave portion 35b. The first heat insulating member 7 is provided between the first package 3 and the second package 6. The first package 3 and the second package 6 are fixed to each other via the first heat insulating member 7.

The second resonator 81 and a plurality of internal terminals 39 are disposed on a bottom surface of the concave portion 36. The second resonator 81 and the plurality of internal terminals 39 are electrically coupled via bonding members B2.

Circuit components 50 such as bypass capacitors are disposed on the bottom surface of the concave portion 36. The circuit components 50 are bonded to the bottom surface of the concave portion 36 by a conductive bonding member (not shown). The circuit components 50 are electrically coupled to the internal wirings (not shown) in the second base substrate 32 via the conductive bonding member (not shown).

A plurality of external terminals 40 are disposed on the lower surface 32B of the second base substrate 32. The oscillator 1 is electrically coupled to an external device (not shown) via the external terminals 40.

The internal terminals 37, the internal terminals 38, the internal terminals 39, and the external terminals 40 are electrically coupled to one another via internal wirings (not shown) in the second base substrate 32.

The second lid 33 has a flat plate shape. The second lid 33 has a lower surface 33A which is a surface facing the second base substrate 32, and an upper surface 33B.

The upper surface 32A of the second base substrate 32 and the lower surface 33A of the second lid 33 are bonded to each other via a sealing member (not shown) so as to close an opening of the concave portion 35. As a result, the concave portion 35 is hermetically sealed, and a second accommodation space S2 is formed in the second package 6. Then, the first resonator 10 is accommodated in the second accommodation space S2. In other words, the first package 3 is accommodated in the second accommodation space S2.

In the embodiment, the second base substrate 32 is made of a ceramic material such as alumina or titania. The second lid 33 is made of a metal material such as Kovar. However, the constituent materials of the second base substrate 32 and the second lid 33 are not particularly limited.

The second accommodation space S2 is airtight and is in the reduced pressure state, preferably in the state close to vacuum. That is, the inside of the second package 6 is depressurized. Accordingly, the second accommodation space S2 can exhibit excellent heat insulating properties, and external heat of the oscillator 1 is less likely to be transferred to the first package 3. Therefore, the first resonator element 2 is less likely to be affected by the external heat, and the first resonator element 2 is easily maintained at the desired temperature by the heat of the heater element 5. An atmosphere of the second accommodation space S2 is not particularly limited.

Next, the first heat insulating member 7 will be described.

The first package 3 is disposed such that the lower surface of the first package, that is, the lower surface 13B of the first lid 13 and the bottom surface of the concave portion 35b face each other.

The first heat insulating member 7 is provided between the first lid 13 of the first package 3 and the concave portion 35b of the second package 6. Specifically, the first heat insulating member 7 is provided between the lower surface 13B of the first lid 13 and the bottom surface of the concave portion 35b. In this manner, the first lid 13 is fixed to the second package 6 via the first heat insulating member 7.

By providing the first heat insulating member 7 between the first package 3 and the second package 6, the external heat of the oscillator 1 is less likely to be transferred to the first package 3. Therefore, the first resonator element 2 is less likely to be affected by the external heat, and the first resonator element 2 is easily maintained at the desired temperature by the heat of the heater element 5.

In addition, the heat of the heater element 5 is less likely to escape to the second package 6 via the first package 3, and the heat of the heater element 5 can be efficiently transferred to the first resonator element 2. Therefore, the heater element 5 can be efficiently driven, and the temperature of the first resonator element 2 can be easily maintained at a desired temperature.

A material constituting the first heat insulating member 7 is not particularly limited as long as the material has a sufficiently low thermal conductivity. As the material constituting the first heat insulating member 7, for example, an insulating resin such as a polyimide resin, a silicone resin, or an epoxy resin can be used. These insulating resins may contain an inorganic material having a sufficiently low thermal conductivity, such as silica, as a filler.

When the material constituting the first heat insulating member 7 has an adhesive force, the first package 3 and the second package 6 can be fixed to each other via the first heat insulating member 7 by using the first heat insulating member 7 as an adhesive. However, the material constituting the first heat insulating member 7 may not have the adhesive force. When the first heat insulating member 7 does not have the adhesive force, the first package 3 and the first heat insulating member 7, and the second package 6 and the first heat insulating member 7 can be respectively fixed via a bonding member such as an adhesive.

In addition, the first heat insulating member 7 includes a plurality of coupling portions 61 disposed to be separated from one another. The plurality of coupling portions 61 are disposed to be separated from one another in the X direction and the Y direction between the lower surface 13B of the first lid 13 and the bottom surface of the concave portion 35b. As a result, a contact area between the first package 3 and the first heat insulating member 7 and a contact area between the second package 6 and the first heat insulating member 7 can be reduced, and the external heat of the oscillator 1 is less likely to be transferred to the first package 3 via the first heat insulating member 7.

In the embodiment, the coupling portion 61 has a columnar shape. However, a shape of the coupling portion 61 is not particularly limited. The coupling portion 61 may have, for example, a frustum shape.

In addition, the first heat insulating member 7 may not include the plurality of coupling portions 61, and may be disposed so as to spread over the entire surface in the X direction and the Y direction without a gap between the lower surface 13B of the first lid 13 and the bottom surface of the concave portion 35b. As a result, the contact area between the first package 3 and the first heat insulating member 7 and the contact area between the second package 6 and the first heat insulating member 7 are increased, and adhesive strength between the first package 3 and the second package 6 is increased. However, the smaller the contact area between the first package 3 and the first heat insulating member 7 and the contact area between the second package 6 and the first heat insulating member 7, the higher the heat insulating properties between the first package 3 and the second package 6, and thus the first heat insulating member 7 preferably includes the plurality of coupling portions 61.

Next, electrical coupling between the first resonator 10 and the second package 6 and electrical coupling between the first circuit element 101 and the second package 6 will be described.

As described above, the plurality of internal terminals 37 and 38 are disposed on the bottom surface of the concave portion 35a included in the second package 6.

The plurality of internal terminals 37 are electrically coupled to the first resonator 10 via conductive bonding wires W5. Specifically, the plurality of internal terminals 37 are electrically coupled to the plurality of external terminals 25 disposed on the upper surface 12B of the first base substrate 12 via the bonding wires W5.

That is, the first package 3 and the second package 6 are electrically coupled to each other via the bonding wires W5.

The plurality of internal terminals 38 are electrically coupled to the first circuit element 101 via conductive bonding wires W6. Specifically, the plurality of internal terminals 38 are electrically coupled to the plurality of coupling terminals 29 disposed on the upper surface of the first circuit element 101 via the bonding wires W6.

That is, the first circuit element 101 and the second package 6 are electrically coupled to each other via the bonding wires W6.

The bonding wires W5 and W6 are metal wires formed of gold, copper, or the like.

Since the bonding wire W5 is a metal wire, the bonding wire W5 can serve as a heat conduction path between the first package 3 and the second package 6. Similarly, since the bonding wire W6 is a metal wire, the bonding wire W6 can serve as a heat conduction path between the first circuit element 101 and the second package 6.

However, since the bonding wires W5 and W6 are elongated linear conductive paths, it is possible to effectively prevent heat conduction as compared with a conductive path formed by metal plating described in the related art.

Therefore, since the first package 3 and the second package 6 are electrically coupled to each other via the bonding wires W5, the external heat of the oscillator 1 is less likely to be transferred from the second package 6 to the first package 3. Therefore, the first resonator element 2 is less likely to be affected by the external heat, and the first resonator element 2 is easily maintained at the desired temperature by the heat of the heater element 5.

In addition, the heat of the heater element 5 is less likely to escape to the second package 6 via the first package 3, and the heat of the heater element 5 can be efficiently transferred to the first resonator element 2. Therefore, the heater element 5 can be efficiently driven, and the temperature of the first resonator element 2 can be easily maintained at a desired temperature.

In addition, since the first circuit element 101 as the control circuit element and the second package 6 are electrically coupled to each other via the bonding wires W6, the external heat of the oscillator 1 is less likely to be transferred to the first package 3 via the second package 6 and the first circuit element 101. Therefore, the first resonator element 2 is less likely to be affected by the external heat, and the first resonator element 2 is easily maintained at the desired temperature by the heat of the heater element 5.

In addition, the heat of the heater element 5 is less likely to escape to the second package 6 via the first package 3 and the first circuit element 101, and the heat of the heater element 5 can be efficiently transferred to the first resonator element 2. Therefore, the heater element 5 can be efficiently driven, and the temperature of the first resonator element 2 can be easily maintained at a desired temperature.

Next, the PLL circuit 43 will be described.

The PLL circuit 43 is a circuit that uses an oscillation signal generated by the oscillation circuit 42 causing the first resonator element 2 to oscillate as a reference signal and outputs an oscillation signal having a predetermined frequency synchronized with the reference signal.

In the embodiment, the oscillation signal output from the PLL circuit 43 is the oscillation signal output from the oscillator 1.

The PLL circuit 43 includes the oscillation circuit 44, the phase comparator 45, the loop filter 47, the dividing circuit 48, and the second resonator 81.

The first circuit element 101 includes a part of the PLL circuit 43. Specifically, the first circuit element 101 includes the oscillation circuit 44, the phase comparator 45, the loop filter 47, and the dividing circuit 48 as a part of the PLL circuit 43.

A voltage-controlled oscillator includes the oscillation circuit 44 and the second resonator 81.

The oscillation circuit 44 is a circuit for causing a second resonator element 82 included in the second resonator 81 to oscillate. The oscillation circuit 44 is a circuit for generating the oscillation signal by outputting an excitation signal for exciting the second resonator element 82 and causing the second resonator element 82 to oscillate.

The phase comparator 45 detects a phase difference between the oscillation signal generated by the oscillation circuit 42 causing the first resonator element 2 to oscillate and the oscillation signal divided by the dividing circuit 48. The phase comparator 45 outputs the detected phase difference as an error signal.

The loop filter 47 is a low-pass filter, and removes a high-frequency component from the error signal output from the phase comparator 45. The loop filter 47 outputs the error signal from which the high-frequency component is removed as a frequency control signal for controlling the voltage-controlled oscillator including the oscillation circuit 44 and the second resonator 81. The frequency control signal is a DC signal converted into a voltage.

The voltage-controlled oscillator including the oscillation circuit 44 and the second resonator 81 oscillates at a frequency corresponding to the voltage of the frequency control signal output from the loop filter 47, and outputs an oscillation signal.

The oscillation signal output from the voltage-controlled oscillator including the oscillation circuit 44 and the second resonator 81 is input to the dividing circuit 48.

The dividing circuit 48 divides the oscillation signal output from the voltage-controlled oscillator including the oscillation circuit 44 and the second resonator 81. The dividing circuit 48 outputs the divided oscillation signal to the phase comparator 45.

In such a PLL circuit 43, a frequency of the oscillation signal output from the voltage-controlled oscillator including the oscillation circuit 44 and the second resonator 81 is a frequency obtained by calculating a frequency of the oscillation signal generated by the oscillation circuit 42 causing the first resonator element 2 to oscillate at a magnification corresponding to a division ratio of the dividing circuit 48.

That is, in such a PLL circuit 43, an oscillation frequency of the second resonator element 82 is controlled based on the oscillation signal generated by the oscillation circuit 42 causing the first resonator element 2 to oscillate.

The configuration of the PLL circuit 43 is not particularly limited. For example, the PLL circuit 43 may be a fractional division PLL circuit or an integer division PLL circuit. The PLL circuit 43 may include both the fractional division PLL circuit and the integer division PLL circuit.

Next, the second resonator 81 will be described.

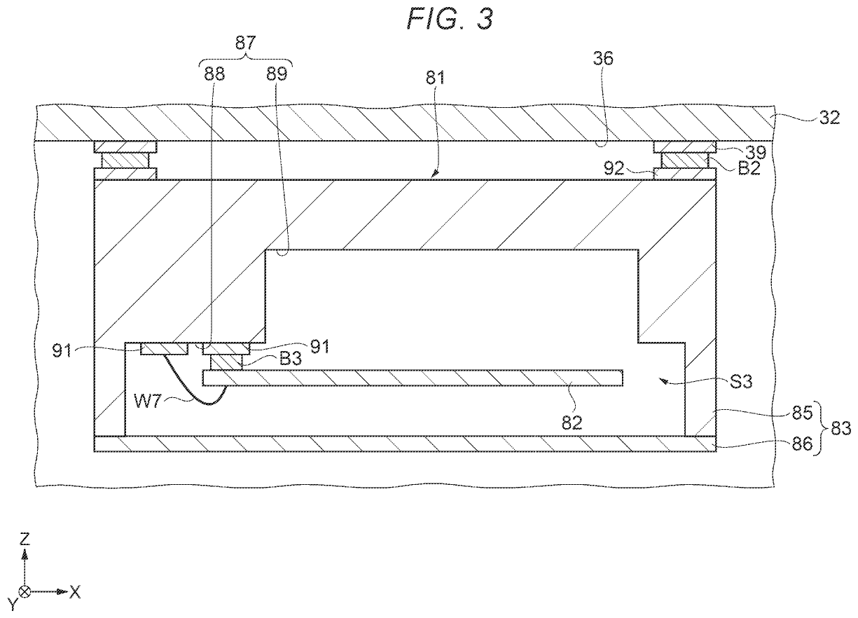

As shown in FIG. 3, the second resonator 81 includes the second resonator element 82 and a third package 83.

The second resonator element 82 is formed of a quartz crystal substrate having a flat plate shape. In the embodiment, the second resonator element 82 is formed of the AC cut quartz crystal substrate. Excitation electrodes (not shown) are provided on an upper surface and a lower surface of the second resonator element 82.

However, the configuration of the second resonator element 82 is not particularly limited. The second resonator element 82 may be formed of, for example, the SC cut quartz crystal substrate or the BT cut quartz crystal substrate other than the AT cut quartz crystal substrate. The second resonator element 82 may be, for example, a resonator element in which a plurality of resonating arms perform flexural resonation in an in-plane direction, or a resonator element in which a plurality of resonating arms perform the flexural resonation in an out-of-plane direction. Further, the first resonator element 2 may be, for example, a resonator element in which a piezoelectric body other than a quartz crystal is used. Further, the second resonator element 82 may be, for example, a SAW resonator, or a MEMS resonator in which a piezoelectric element is disposed on a semiconductor substrate made of silicon or the like.

The third package 83 includes a third base substrate 85 and a third lid 86.

The third base substrate 85 has a box shape in which a concave portion 87 is formed. The concave portion 87 has a shape that opens in a lower surface of the third base substrate 85, and is recessed from the lower surface toward an upper surface of the third base substrate 85.

The third lid 86 has a flat plate shape. The third lid 86 is disposed such that an upper surface of the third lid 86 faces the lower surface of the third base substrate 85.

The lower surface of the third base substrate 85 and the upper surface of the third lid 86 are bonded to each other via a sealing member (not shown) so as to close an opening of the concave portion 87. As a result, the concave portion 87 is hermetically sealed, and a third accommodation space S3 is formed in the third package 83. Then, the second resonator element 82 is accommodated in the third accommodation space S3.

In the embodiment, the third base substrate 85 is made of a ceramic material such as alumina or titania. The third lid 86 is made of a metal material such as Kovar. However, the constituent materials of the third base substrate 85 and the third lid 86 are not particularly limited.

The third accommodation space S3 is airtight and is in the reduced pressure state, preferably in the state close to vacuum. That is, the inside of the third package 83 is depressurized. As a result, a viscosity resistance of the third accommodation space S3 is reduced, and resonation characteristics of the second resonator element 82 are improved. An atmosphere of the third accommodation space S3 is not particularly limited.

The concave portion 87 includes a plurality of concave portions. In the embodiment, the concave portion 87 includes a concave portion 88 that opens in the lower surface of the third base substrate 85, and a concave portion 89 that opens in a bottom surface of the concave portion 88 and has an opening smaller than that of the concave portion 88. However, the configuration of the concave portion 87 is not particularly limited.

A plurality of internal terminals 91 are disposed on the bottom surface of the concave portion 88. The plurality of internal terminals 91 are electrically coupled to the second resonator element 82 via conductive bonding members B3 and conductive bonding wires W7. Specifically, the internal terminal 91 is electrically coupled to the excitation electrodes (not shown) provided on the upper surface and the lower surface of the second resonator element 82 via the bonding members B3 and the bonding wires W7. A method for supporting the second resonator element 82 is not limited to the one-point support by the bonding member B3, and may be, for example, the two-point support by two bonding members.

The bonding member B3 is a metal bump formed of gold, copper, or the like. The bonding wire W7 is a metal wire formed of gold, copper, or the like.

One end portion of the second resonator element 82 is fixed to the bottom surface of the concave portion 88 via the bonding member B3.

A plurality of external terminals 92 are disposed on the upper surface of the third base substrate 85. The external terminals 92 are electrically coupled to the internal terminals 91 via an internal wiring (not shown) formed in the third base substrate 85.

As shown in FIGS. 1 and 3, the external terminals 92 are electrically coupled to the internal terminals 39 disposed on the bottom surface of the concave portion 36 of the second base substrate 32 via the bonding members B2.

The third package 83 accommodating the second resonator element 82 is attached to the second package 6 via the bonding members B2.

As described above, the first heat insulating member 7 is provided between the first package 3 and the second package 6. Therefore, the heat of the heater element 5 attached to the first package 3 is less likely to be transferred to the third package 83 attached to the second package 6. Since the heat of the heater element 5 is less likely to be transferred to the second resonator element 82 accommodated in the third package 83, the temperature fluctuation of the second resonator element 82 is prevented, and it is possible to prevent deterioration of a phase noise characteristic of the oscillation signal output from the voltage-controlled oscillator including the oscillation circuit 44 and the second resonator 81.

The oscillator 1 is described above.

In the embodiment, the oscillator 1 includes the PLL circuit 43, but the PLL circuit 43 may be omitted. When the PLL circuit 43 is omitted, the oscillation signal generated by the oscillation circuit 42 causing the first resonator element 2 to oscillate is the oscillation signal output from the oscillator 1.

As described above, according to the embodiment, the following effects can be obtained.

The oscillator 1 includes the first resonator element 2, the first package 3 that accommodates the first resonator element 2 and includes the first base substrate 12 as the base and the first lid 13 as the lid, the heater element 5 that is attached to the first package 3, the second package 6 that accommodates the first package 3, the first circuit element 101 as the control circuit element that is bonded to the upper surface 12B of the first base substrate 12 of the first package 3, the upper surface 12B being the surface on the side opposite to the first lid 13, and controls the heater element 5, and the first heat insulating member 7 provided between the first lid 13 of the first package 3 and the second package 6.

Accordingly, the external heat of the oscillator 1 is less likely to be transferred to the first package 3. Therefore, the first resonator element 2 is less likely to be affected by the external heat, and the first resonator element 2 is easily maintained at the desired temperature by the heat of the heater element 5. That is, the oscillation characteristics of the oscillator 1 are less likely to be affected by the ambient temperature, and the oscillation characteristics of the oscillator 1 are stabilized.

### 2. Second Embodiment

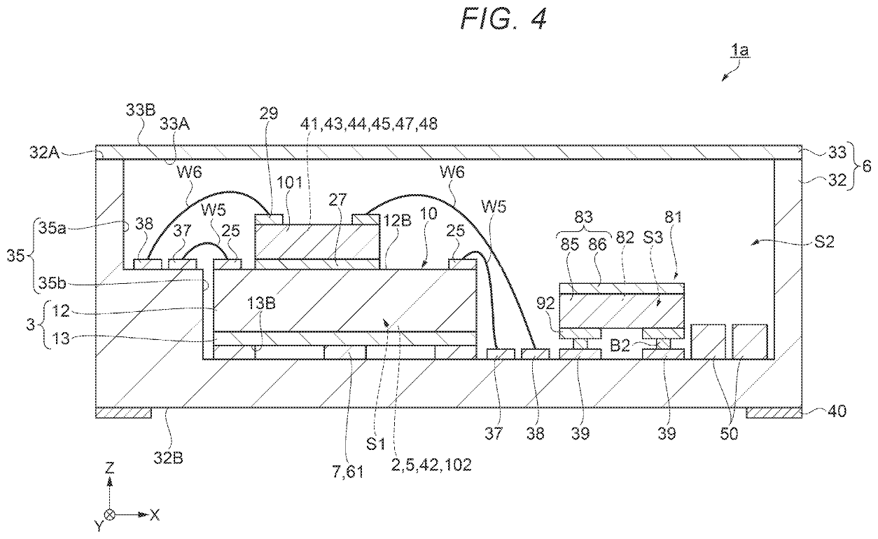

Next, an oscillator 1a according to a second embodiment will be described with reference to FIG. 4.

The oscillator 1a according to the second embodiment is similar to the oscillator 1 according to the first embodiment except that a shape of the second package 6 is different, and the concave portion 36 of the second base substrate 32 is omitted, that the second resonator 81, the circuit components 50, and the internal terminals 39 disposed in the concave portion 36 are disposed in the concave portion 35, that the second resonator 81 is disposed upside down, and that the internal terminals 37 and 38 are disposed in the concave portion 35a and the concave portion 35b.

The same components as those of the first embodiment described above are denoted by the same reference numerals, and the description thereof will be omitted.

As shown in FIG. 4, the second base substrate 32 has a box shape having the concave portion 35 that opens in the upper surface 32A. In the embodiment, the second base substrate 32 does not have the concave portion 36 that opens in the lower surface 32B. Therefore, the second base substrate 32 has a substantially U shape in a longitudinal sectional view.

The concave portion 35 includes the concave portion 35a and the concave portion 35b.

The plurality of internal terminals 37 and 38 are disposed on the bottom surface of the concave portion 35a and the bottom surface of the concave portion 35b.

The internal terminals 37 are electrically coupled to the first package 3 via the bonding wires W5. The internal terminals 38 are electrically coupled to the first circuit element 101 via the bonding wires W6.

The first heat insulating member 7 is provided between the lower surface 13B of the first lid 13 and the bottom surface of the concave portion 35b. The first lid 13 is fixed to the second package 6 via the first heat insulating member 7.

The internal terminals 39 and the circuit components 50 are disposed on the bottom surface of the concave portion 35b.

The second resonator 81 is disposed on the bottom surface of the concave portion 35b.

In the embodiment, the second resonator 81 is disposed upside down as compared with the first embodiment. Specifically, the second resonator 81 is disposed in a posture in which the third lid 86 faces an opening side of the concave portion 35b, and the third base substrate 85 faces a bottom surface side of the concave portion 35b.

The internal terminals 39 and the external terminals 92 disposed on the lower surface of the third base substrate 85 are electrically coupled to each other via the bonding members B2.

In the embodiment, similarly to the first embodiment, the first heat insulating member 7 is provided between the lower surface 13B of the first lid 13 and the bottom surface of the concave portion 35b.

Accordingly, external heat of the oscillator 1a is less likely to be transferred to the first package 3. Therefore, the first resonator element 2 is less likely to be affected by the external heat, and the first resonator element 2 is easily maintained at the desired temperature by the heat of the heater element 5.

In addition, the heat of the heater element 5 is less likely to escape to the second package 6 via the first package 3, and the heat of the heater element 5 can be efficiently transferred to the first resonator element 2. Therefore, the heater element 5 can be efficiently driven, and the temperature of the first resonator element 2 can be easily maintained at a desired temperature.

As described above, according to the embodiment, the same effects as those of the first embodiment can be obtained.

### 3. Third Embodiment

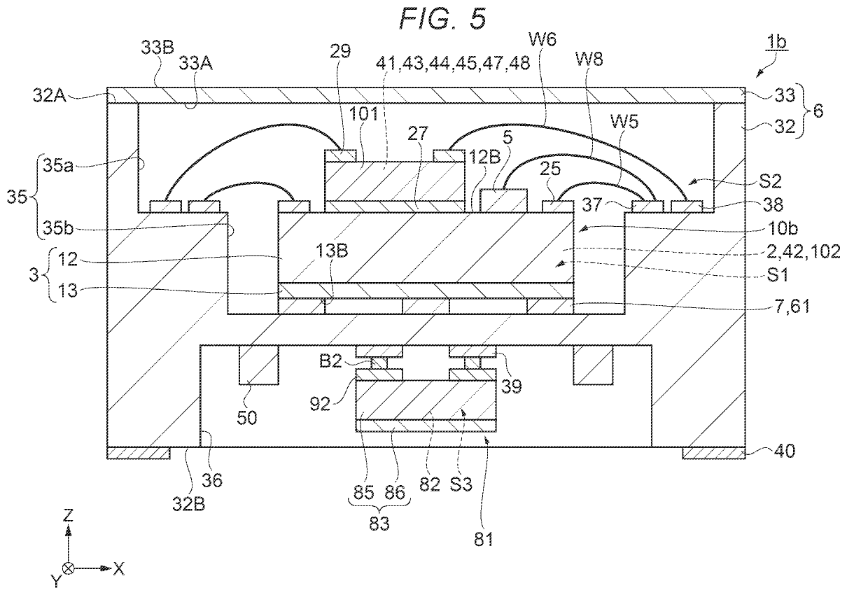

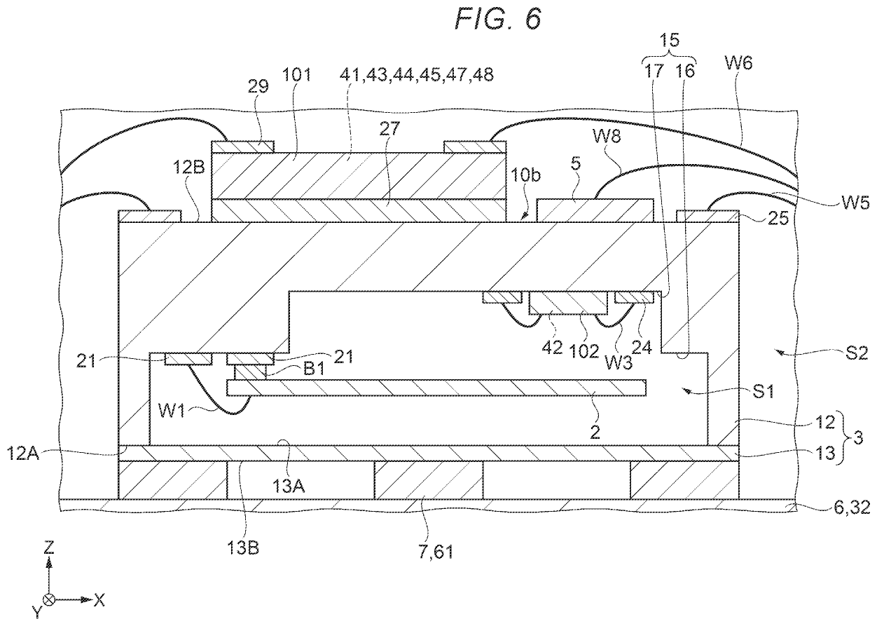

Next, an oscillator 1b according to a third embodiment will be described with reference to FIGS. 5 and 6.

The oscillator 1b according to the third embodiment is similar to the oscillator 1 according to the first embodiment except that the heater element 5 is fixed onto the first package 3.

The same components as those of the first embodiment described above are denoted by the same reference numerals, and the description thereof will be omitted.

As shown in FIGS. 5 and 6, the heater element 5 is attached to the first package 3 included in the first resonator 10b. However, the heater element 5 is not accommodated in the first package 3, and the heater element 5 is fixed onto the first package 3. Specifically, the heater element 5 is bonded to the upper surface 12B of the first package 3 via a bonding member (not shown). The expression “fixed onto the first package 3” means that the heater element 5 is fixed not only to the upper surface of the first package 3 but also to the outer peripheral surface of the first package 3. That is, the heater element 5 may be fixed to, for example, a side surface of the first package 3.

By disposing the heater element 5 on the first package 3, the number of components accommodated in the first package 3 can be reduced. Therefore, it is possible to reduce a size of the first package 3.

As shown in FIG. 5, in the embodiment, the heater element 5 is electrically coupled to the internal terminal 37 disposed on the bottom surface of the concave portion 35a via a conductive bonding wire W8.

The bonding wire W8 is a metal wire formed of gold, copper, or the like.

The heater element 5 is not limited to be electrically coupled to the internal terminal 37 and may be electrically coupled to the internal terminal 38 or the coupling terminal 29 as long as the heater element 5 is electrically coupled to the heater control circuit 41 included in the first circuit element 101.

In the embodiment, similarly to the first embodiment, the first heat insulating member 7 is provided between the lower surface 13B of the first lid 13 and the bottom surface of the concave portion 35b.

Accordingly, external heat of the oscillator 1b is less likely to be transferred to the first package 3. Therefore, the first resonator element 2 is less likely to be affected by the external heat, and the first resonator element 2 is easily maintained at the desired temperature by the heat of the heater element 5.

In addition, the heat of the heater element 5 is less likely to escape to the second package 6 via the first package 3, and the heat of the heater element 5 can be efficiently transferred to the first resonator element 2. Therefore, the heater element 5 can be efficiently driven, and the temperature of the first resonator element 2 can be easily maintained at a desired temperature.

As described above, according to the embodiment, the same effects as those of the first embodiment can be obtained.

### 4. Fourth Embodiment

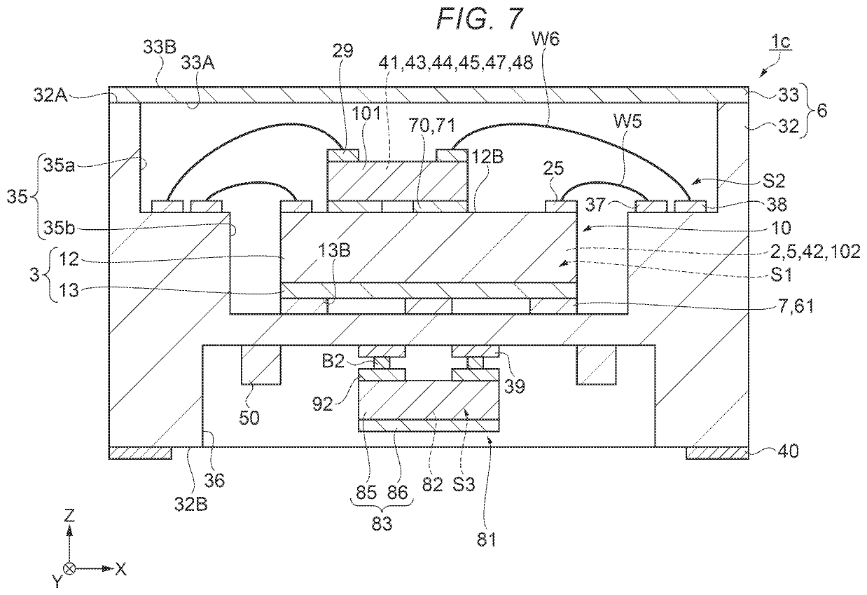

Next, an oscillator 1c according to a fourth embodiment will be described with reference to FIG. 7.

The oscillator 1c according to the fourth embodiment is similar to the oscillator 1 according to the first embodiment except that a second heat insulating member 70 is provided between the first circuit element 101 and the first package 3 instead of the bonding member 27 that bonds the first circuit element 101 and the first package 3.

The same components as those of the first embodiment described above are denoted by the same reference numerals, and the description thereof will be omitted.

As shown in FIG. 7, the second heat insulating member 70 is provided between the first circuit element 101 and the first package 3. Specifically, the second heat insulating member 70 is provided between the lower surface of the first circuit element 101 and the upper surface 12B of the first base substrate 12.

By providing the second heat insulating member 70 between the first circuit element 101 and the first package 3, the first circuit element 101 is bonded to the first package 3 via the second heat insulating member 70.

By providing the second heat insulating member 70 between the first circuit element 101 and the first package 3, the heat of the heater element 5 is less likely to escape to the first circuit element 101 via the first package 3, and the heat of the heater element 5 can be efficiently transferred to the first resonator element 2. Therefore, the heater element 5 can be further efficiently driven, and the temperature of the first resonator element 2 can be further easily maintained at the desired temperature.

A material constituting the second heat insulating member 70 is not particularly limited as long as the material has a sufficiently low thermal conductivity. As the material constituting the second heat insulating member 70, the same material as that of the first heat insulating member 7 can be used. For example, an insulating resin such as a polyimide resin, a silicone resin, or an epoxy resin can be used. These insulating resins may contain an inorganic material having a sufficiently low thermal conductivity, such as silica, as a filler.

In addition, the second heat insulating member 70 includes a plurality of coupling portions 71 disposed to be separated from one another. The plurality of coupling portions 71 are disposed to be separated from one another in the X direction and the Y direction between the lower surface of the first circuit element 101 and the upper surface 12B of the first base substrate 12. As a result, a contact area between the first circuit element 101 and the second heat insulating member 70 and a contact area between the first package 3 and the second heat insulating member 70 can be reduced, and the heat of the heater element 5 is less likely to escape to the first circuit element 101 via the first package 3.

In the embodiment, the coupling portion 71 has a columnar shape. However, a shape of the coupling portion 71 is not particularly limited. The coupling portion 71 may have, for example, a frustum shape.

In addition, the second heat insulating member 70 may not include the plurality of coupling portions 71, and may be disposed so as to spread over the entire surface in the X direction and the Y direction without a gap between the lower surface of the first circuit element 101 and the upper surface 12B of the first base substrate 12. As a result, the contact area between the first circuit element 101 and the second heat insulating member 70 and the contact area between the first package 3 and the second heat insulating member 70 are increased, and adhesive strength between the first circuit element 101 and the first package 3 is increased. However, the smaller the contact area between the first circuit element 101 and the second heat insulating member 70 and the contact area between the first package 3 and the second heat insulating member 70, the higher the heat insulating properties between the first circuit element 101 and the first package 3, and thus the second heat insulating member 70 preferably includes the plurality of coupling portions 71.

According to the embodiment, following effects can be obtained in addition to the effects of the first embodiment. Since the first circuit element 101 is bonded to the first package 3 via the second heat insulating member 70, the heat of the heater element 5 is less likely to escape to the first circuit element 101 via the first package 3. Therefore, the heater element 5 can be further efficiently driven, and the temperature of the first resonator element 2 can be further easily maintained at the desired temperature.

The oscillators 1, 1a, 1b, and 1c are described above. The present disclosure is not limited thereto, and a configuration of each part can be replaced with a configuration having the same function. In addition, any other constituents may be added to the present disclosure. The embodiments may be combined as appropriate.

For example, the heater element 5 may include a temperature sensor, and the heater control circuit 41 may control the heater element 5 based on an output signal of the temperature sensor included in the heater element 5.

For example, the first circuit element 101 may include the oscillation circuit 42 that causes the first resonator element 2 to oscillate so as to generate an oscillation signal. When the first circuit element 101 includes the oscillation circuit 42, the second circuit element 102 may be omitted.

What is claimed is:

1. An oscillator comprising:
a first resonator element;
a first package accommodating the first resonator element and including a base and a lid;
a heater element attached to the first package;
a second package accommodating the first package;
a control circuit element bonded to a surface of the base of the first package on a side opposite to the lid and configured to control the heater element; and
a first heat insulating member provided between the lid of the first package and the second package.

2. The oscillator according to claim 1, wherein
the heater element is accommodated in the first package.

3. The oscillator according to claim 1, wherein
the control circuit element and the second package are electrically coupled to each other via a bonding wire.

4. The oscillator according to claim 1, wherein
the control circuit element is bonded to the first package by a conductive adhesive.

5. The oscillator according to claim 1, wherein
the control circuit element is bonded to the first package via a second heat insulating member.

6. The oscillator according to claim 1, further comprising:
an oscillation circuit configured to cause the first resonator element to oscillate so as to generate an oscillation signal;
a second resonator element configured to control an oscillation frequency based on the oscillation signal from the oscillation circuit; and
a third package accommodating the second resonator element, wherein
the third package is attached to the second package.

7. The oscillator according to claim 1, wherein
an inside of the second package is depressurized.

8. The oscillator according to claim 1, wherein
the first heat insulating member includes a plurality of coupling portions.
